(19) United States
(12) Patent Application Publication
(10) Pub. No.: US 2026/0123035 A1
(43) Pub. Date: Apr. 30, 2026

(54) ISOLATION STRUCTURE FOR N EPITAXY-BASED SILICON CARBIDE DEVICE, AND N EPITAXY-BASED SILICON CARBIDE HIGH AND LOW VOLTAGE INTEGRATED DEVICE AND PREPARATION METHOD THEREFOR

(71) Applicant: SOUTHEAST UNIVERSITY, Nanjing (CN)

(72) Inventors: Long ZHANG, Nanjing (CN); Weifeng SUN, Nanjing (CN); Siyang LIU, Nanjing (CN); Yong GU, Nanjing (CN); Jie MA, Nanjing (CN); Hongyang WEN, Nanjing (CN); Longxing SHI, Nanjing (CN)

(73) Assignee: SOUTHEAST UNIVERSITY, Nanjing (CN)

(21) Appl. No.: 19/152,020

(22) PCT Filed: Jul. 26, 2024
(86) PCT No.: PCT/CN2024/107704

§ 371 Date: Jul. 30, 2025

(30) Foreign Application Priority Data
Feb. 21, 2024 (CN) 202410191179.7

(51) Int. Cl. H10D 84/83; H10D 30/01; H10D 30/65; H10D 62/10; H10D 62/832; H10D 64/66; H10D 84/01

(52) U.S. Cl. CPC H10D 84/83138; H10D 30/027; H10D 30/0281; H10D 30/0289; H10D 30/65; H10D 30/658; H10D 62/124; H10D 62/8325; H10D 64/661; H10D 84/0142

(57) ABSTRACT

An isolation structure for an N epitaxy-based silicon carbide device, and an N epitaxy-based silicon carbide high and low voltage integrated device and a preparation method therefor are provided. The isolation structure includes N-type substrate, a first isolation trench and a second isolation trench to form a high-voltage region, a low-voltage region and a level shift region, a second P-type doped region is arranged at the bottom of the low-voltage region and of the level shift region, a second N-type doped region is arranged on the second P-type doped region in the low-voltage region, and back-to-back PN junctions are formed by the N-type drift region, the second P-type doped region in the low-voltage region, and the second N-type doped region. A DMOS device is arranged in a high-voltage region, low-voltage devices are arranged in a low-voltage region, and an LDMOS device is arranged in a level shift region.

### CROSS REFERENCE TO THE RELATED APPLICATIONS

This application is the national phase entry of International Application No. PCT/CN2024/107704, filed on Jul. 26, 2024, which is based upon and claims priority to Chinese Patent Application No. 202410191179.7, filed on Feb. 21, 2024, the entire contents of which are incorporated herein by reference.

### TECHNICAL FIELD

The application relates to the field of semiconductor manufacturing, in particular, to an isolation structure for an N epitaxy-based silicon carbide device, and an N epitaxy-based silicon carbide high and low voltage integrated device and preparation method therefor.

### BACKGROUND

At present, the requirements for power devices in the semiconductor industry are becoming increasingly higher. The performance of traditional silicon-based metal-oxide-semiconductor field effect transistor and silicon-based insulated-gate bipolar transistor power devices has approximated to the theoretic limit of their materials, and such power devices cannot satisfy the requirements of a new generation of power electronic systems anymore. Compared with traditional silicon materials, silicon carbide, as a wide bandgap semiconductor material, has the outstanding advantages of wide bandgap, high critical breakdown field, high saturation drift velocity of electrons, high thermal conductivity and the like, and is a perfect semiconductor material in high-power, high-temperature, high-frequency and anti-irradiation application scenarios.

Silicon carbide power devices have a broad application prospect in high-temperature and high-irradiation fields such as the aerospace field, the new energy vehicle field, the energy exploration drilling field and the nuclear power field because of their material advantages. At present, drive circuits and protection circuits used together with silicon carbide power devices are still based on silicon and have poor high-temperature resistance and irradiation resistance, severely limiting the application range of the silicon carbide power devices. The integration of a silicon carbide half-bridge drive circuit and a silicon carbide power device on a same substrate can reduce the parasitic effect and improve the system reliability. However, although existing silicon carbide integrated devices can realize monolithic integration, there is serious current interference between high and voltage devices, and the interaction between the potential of the power device and the potential of a substrate of the drive circuit severely compromises the device performance.

### SUMMARY

In view of the defects in the prior art, the invention provides an isolation structure for an N epitaxy-based silicon carbide device, and an N epitaxy-based silicon carbide high and low voltage integrated device and preparation method therefor.

The isolation structure for an N epitaxy-based silicon carbide device provided by the invention includes an N-type substrate, wherein an N-type drift region is arranged on the N-type substrate, a first isolation trench in which an oxide is deposited and a second isolation trench in which the oxide is deposited are arranged on the N-type drift region to form a high-voltage region, a low-voltage region and a level shift region, a second P-type doped region is arranged at a bottom of the low-voltage region and a bottom of the level shift region, a second N-type doped region is arranged on the second P-type doped region in the low-voltage region, and back-to-back PN junctions are formed by the N-type drift region, the second P-type doped region in the low-voltage region, and the second N-type doped region.

The N epitaxy-based silicon carbide high and low voltage integrated device provided by the invention includes an isolation structure, wherein:
the isolation structure includes an N-type substrate, an N-type drift region is arranged on the N-type substrate, a first isolation trench in which an oxide is deposited and a second isolation trench in which the oxide is deposited are arranged on the N-type drift region to form a high-voltage region, a low-voltage region and a level shift region, a second P-type doped region is arranged at a bottom of the low-voltage region and a bottom of the level shift region, a second N-type doped region is arranged on the second P-type doped region in the low-voltage region, and back-to-back PN junctions are formed by the N-type drift region, the second P-type doped region in the low-voltage region, and the second N-type doped region;
a power DMOS device is arranged in the high-voltage region, low-voltage devices are arranged in the low-voltage region, and a high-voltage LDMOS device is arranged in the level shift region;
a sixth N-type heavily doped region is arranged on the second N-type doped region, a third epitaxial layer is arranged on the second P-type doped region in the level shift region, a third N-type doped region is arranged on the third epitaxial layer, a seventh N-type heavily doped region used as a drain of the high-voltage LDMOS device is arranged on the third N-type doped region, and the sixth N-type heavily doped region is connected to the seventh N-type heavily doped region by means of a fifth drain metal electrode to control a potential of the second N-type doped region.

The preparation method for an N epitaxy-based silicon carbide high and low voltage integrated device provided by the invention includes the following steps:
acquiring a silicon carbide N-type substrate;
epitaxially growing an N-type drift region on one surface of the N-type substrate; performing ion implantation on the N-type drift region to form a second P-type doped region, a first P-type doped region and first N-type doped regions;
growing a P-type epitaxial layer on surfaces of the second P-type doped region, part of the N-type drift region, the first P-type doped region and the first N-type doped regions, and forming a first epitaxial layer and a third epitaxial layer;
performing ion implantation on the third epitaxial layer above the second P-type doped region to form a third N-type doped region and a second N-type doped region; then, performing ion implantation on the third N-type doped region to form a third P-type doped region and a fourth P-type doped region;
performing ion implantation on the first epitaxial layer above the first N-type doped regions, the second N-type doped region, the third P-type doped region, the fourth P-type doped region and the third epitaxial layer to form a first P-type heavily doped region, a second P-type heavily doped region, a third P-type heavily doped region, a fourth P-type heavily doped region, a fifth P-type heavily doped region, a sixth P-type heavily doped region and a seventh P-type heavily doped region;
performing ion implantation to form first N-type heavily doped regions, the number of which is twice that of the first P-type heavily doped region, in the first epitaxial layer above the first N-type doped regions, form a second N-type heavily doped region and a sixth N-type heavily doped region in the second N-type doped region, form a third N-type heavily doped region and a fourth N-type heavily doped region in the third P-type doped region, form a fifth N-type heavily doped region in the fourth P-type doped region, form a seventh N-type heavily doped region in the third N-type doped region, and form an eighth N-type heavily doped region in the third epitaxial layer;
performing wet oxidation after high-temperature annealing, growing a gate-oxide dielectric on a surface of a current local device structure, and taking the gate-oxide dielectric above the second N-type doped region between the second P-type heavily doped region and the third P-type heavily doped region as a second planar gate-oxide dielectric, the gate-oxide dielectric above the third P-type doped region between the third N-type heavily doped region and the fourth N-type heavily doped region as a third planar gate-oxide dielectric, and the gate-oxide dielectric above the third epitaxial layer between the third N-type doped region and the eighth N-type heavily doped region as a fourth planar gate-oxide dielectric;
respectively depositing a second polysilicon gate, a third polysilicon gate and a fourth polysilicon gate on the second planar gate-oxide dielectric, the third planar gate-oxide dielectric and the fourth planar gate-oxide dielectric;
respectively etching trenches between the first epitaxial layer and the second N-type doped region, between the second N-type doped region and the third epitaxial layer, and in the first epitaxial layer above the first P-type doped region and depositing an oxide to form a first isolation trench, a second isolation trench and an oxide trench, performing etching in the oxide trench and forming a first trench gate-oxide dielectric, and depositing polysilicon in the first trench gate-oxide dielectric to form a first polysilicon gate; and
depositing an oxide layer on a device surface in a current state to form an interlayer dielectric, etching through-holes in the interlayer dielectric and depositing a metal layer on the interlayer dielectric, and etching the metal layer to form a first source metal electrode, a second drain metal electrode, a second source metal electrode, a third drain metal electrode, a third source metal electrode, a fourth drain metal electrode, a first gate metal electrode, a fourth source metal electrode, a fifth drain metal electrode and a fifth source metal electrode; depositing metal in a high-voltage region on the other surface of the N-type substrate, and forming a first drain metal electrode.

Compared with the prior art, the invention has the following beneficial effects:

The N epitaxy-based silicon carbide high and low voltage integrated device provided by the invention may be divided into the high-voltage region, the low-voltage region and the level shift region. The second P-type doped region is formed above the N-type drift region in the low-voltage region and the level shift region by multiple times of high-energy ion implantation. A reverse-biased PN junction formed by the second P-type doped region and the drift region can completely prevent the influence of a high voltage of the drain of the power DMOS device on the potential of low-voltage devices in a drive circuit. The second N-type doped region extending deep to the drift region is formed in the epitaxial layer in the low-voltage region by multiple times of high-energy ion implantation to transform the epitaxial layer in the low-voltage region to be N-type, and low-voltage devices are manufactured in the second N-type doped region. A reverse-biased PN junction is formed by the doped region and the second P-type doped region formed above the drift region, such that the potential of the power DMOS device will not be affected even if the potential of a drive substrate of a high-side transistor is high. Moreover, the second isolation trench is arranged between the high-voltage region and the low-voltage region and extends deep below the P-type doped region in the drift region, such that transverse current interference between high-voltage devices and low-voltage devices can be completely prevented. Under the condition that monolithic integration of a silicon carbide power device and a drive or protection circuit thereof is realized, longitudinal potential interaction is avoided by means of two back-to-back PN junctions, and transverse current interference is avoided by means of deep trenches, thus improving the performance and reliability of a silicon carbide half-bridge drive circuit. The integrated device further includes the level shift region, in which the LDMOS device is arranged to control the potential of the substrate in the low-voltage region.

According to the isolation structure for an N epitaxy-based silicon carbide device, and the N epitaxy-based silicon carbide high and low voltage integrated device and the preparation method therefor, the interference between high and low voltages is eliminated by means of the isolation structure, and high-voltage devices and low-voltage devices are integrated on the same substrate. The high-voltage DMOS device works as a power device, and the low-voltage NMOS, the low-voltage PMOS and the low-voltage JFET device form a half-bridge drive or protection circuit, or the like. A reverse-biased PN junction formed by the second P-type doped region and the N-type drift region in the drift region can completely prevent the influence of a high voltage of the drain of the power DMOS device on the potential of the substrate of the low-voltage devices. A reverse-biased PN junction formed by the second N-type doped region on the epitaxial layer and the second P-type doped region above the drift region eliminates the influence of the potential of the substrate of the drive circuit on the potential of the power DMOS device. The second isolation trench is arranged between the high-voltage region and the low-voltage region, the first isolation trench is arranged between the low-voltage region and the level shift region, and the isolation trenches extend deep below the second P-type doped region, such that transverse current interference between low-voltage devices and high-voltage devices can be completely prevented. In a case where the silicon carbide high and low voltage integrated device is used as a gate drive circuit of a half-bridge low-side transistor, the potential of the epitaxial layer in the low-voltage region is 0. In a case where the silicon carbide high and low voltage integrated device is used as a gate drive circuit of a half-bridge high-side transistor, the LDMOS device is turned off to increase the potential of the epitaxial layer in the low-voltage region.

### BRIEF DESCRIPTION OF THE DRAWINGS

The embodiments and/or examples of the invention disclosed here are better described and explained with reference to one or more drawings. Additional details or examples used for describing the drawings should not be construed as limitations of the scope of any one of the invention disclosed here, the embodiments and/or examples described here and currently understood optimal modes of the invention.

FIG. 1 is a schematic diagram of a high and low voltage isolation structure for an N epitaxy-based silicon carbide high and low voltage integrated device according to one embodiment of the application;

FIG. 2 is a schematic structural diagram of the N epitaxy-based silicon carbide high and low voltage integrated device according to one embodiment of the application;

FIG. 3 is a schematic structural diagram of the silicon carbide high and low voltage integrated device used as a drive circuit of a half-bridge low-side transistor according to one embodiment of the application;

FIG. 4 is a schematic structural diagram of the silicon carbide high and low voltage integrated device used as a drive circuit of a half-bridge high-side transistor according to one embodiment of the application;

FIG. 5 is a flow diagram of a preparation method for the N epitaxy-based silicon carbide high and low voltage integrated device according to one embodiment of the application;

FIGS. 6A-6S are sectional views in the process of preparing a silicon carbide high and low voltage integrated device by the method shown in FIGS. 6A-6S according to one embodiment of the application.

### DETAILED DESCRIPTION OF THE EMBODIMENTS

To gain a better understanding of the invention, the invention will be described more comprehensively with reference to related accompanying drawings, wherein preferred embodiments of the invention are illustrated. However, the invention may be implemented in many different forms and will not be limited to the embodiments described here. On the contrary, these embodiments are provided for a more thorough and comprehensive understanding of the contents disclosed by the invention.

Unless otherwise defined, all technical and scientific terms used here have the same meanings as commonly understood by those skilled in the art. Terms used in the description of the invention are merely for the purpose of describing specific embodiments and are not intended to limit the invention. The term “and/or” used here indicates the inclusion of any one and all combinations of one or more related items listed.

It should be understood that when an element or layer is referred to as being “located on,” “adjacent to,” “connected to” or “coupled to” another element or layer, it may be directly located on, adjacent to, connected to or coupled to the other element or layer, or there may be an element or layer between these two elements or layers. On the contrary, when an element or layer is referred to as being “directly located on,” “directly adjacent to,” “directly connected to” or “directly coupled to” another element or layer, there is no element or layer between these two elements or layers. As for “connected” involved in the description, if there is an electrical signal or data transmission between connected circuits, modules or units, it should be construed as “electrical connection,” “communication connection,” or the like. It should be understood that although terms such as “first,” “second” and “third” may be used to describe various elements, components, regions, layers and/or parts, these elements, components, regions, layers and/or parts should not be limited by these terms. These terms are merely used to distinguish one element, component, region, layer or part from another element, component, region, layer or part. Therefore, a first element, component, region, layer or part discussed below may be expressed as a second element, component, region, layer or part without deviating from the teaching of the invention.

Spatial relation terms such as “below,” “underneath,” “lower,” “under,” “above” and “over” may be used here to describe the relations of one element or feature with other elements or features in the drawings. It should be understood that in addition to the orientations in the drawings, the spatial relation terms are also intended to include different orientations of devices in use and operation. For example, if a device in the drawings turns, an element or feature described as being located “below,” “underneath” or “under” the other element or feature should be changed as being located “above” the other element or feature. Therefore, the illustrative terms “below” and “under” may include two orientations. When the device has other orientations (is rotated by 90° or in other orientations), the spatial relation terms should be interpreted accordingly.

Terms used here are merely for the purpose of describing specific embodiments and should not be construed as limitations of the invention. Here, the singular form “a/an,” “one” and “the/said” also intend to include the plural form, unless otherwise expressly stated. It should be understood that “at least one” refers to one or more, and “multiple” refers to two or more. “At least part of an element” refers to all or part of the element. It should also be understood that the term “formed by” and/or “include,” if used here, indicates the existence of said feature, integer, step, operation, element and/or component and does not exclude the existence or addition of one or more other features, integers, steps, operations, elements, parts and/or groups. Here, the term “and/or”is used to indicate any one and all combinations of related items listed.

Here, the embodiments of the invention are described with reference to cross-sectional views used as schematic diagrams of ideal embodiments (and intermediate structures) of the invention, such that changes in shape caused by, for example, manufacturing techniques and/or tolerance can be predicted. Therefore, the embodiments of the invention should not be limited to the specific shapes illustrated here and should include shape deviations caused by, for example, manufacturing. For example, a rectangular implanted region shown below generally has a circular or curved feature and/or an implantation concentration gradient and does not mean a binary change from the implanted region to a non-implanted region. Similarly, a hidden region formed by implantation may lead to some implantation in the hidden region and surfaces passing by when implantation is performed. Therefore, regions shown in the drawings are essentially illustrative, and shapes of the regions in the drawings are neither intended to show the actual shapes of devices nor intended to limit the scope of the invention.

Vocabularies in the semiconductor field used here are technical vocabularies commonly used by those skilled in the art, for example, to distinguish the doping concentration of P-type and N-type impurities, P+ indicates heavily doped P type, P indicates moderately doped P type, P− indicates a lightly doped P type, N+ indicates heavily doped N type, N indicates moderately doped N type, and N− indicates a lightly doped N type.

In view of the problem of serious interference in monolithic integration of existing silicon carbide high and low voltage circuits, the application provides an isolation structure for an N epitaxy-based silicon carbide device, and an N epitaxy-based silicon carbide high and low voltage integrated device and preparation method therefor.

### Embodiment 1

An isolation structure for an N epitaxy-based silicon carbide device includes: an N-type substrate 110, wherein an N-type drift region 120 is arranged on the N-type substrate 110, a first isolation trench 23144 in which an oxide is deposited and a second isolation trench 12144 in which the oxide is deposited are arranged on the N-type drift region 120 to form a high-voltage region 10, a low-voltage region 20 and a level shift region 30, a second P-type doped region 122 is arranged at the bottom of the low-voltage region 20 and the bottom of the level shift region 30, a second N-type doped region 20132 is arranged on the second P-type doped region 122 in the low-voltage region 20, and back-to-back PN junctions are formed by the N-type drift region 120, the second P-type doped region 122 in the low-voltage region 20, and the second N-type doped region 20132.

In this embodiment, the doping concentration of the second P-type doped region 122 at the bottom of the low-voltage region 20 and the bottom of the level shift region 30 should be greater than 1 E17 cm⁻³, such that the PN junction formed by the second P-type doped region 122 is able to withstand a 1.2 kV voltage.

### Embodiment 2

An N epitaxy-based silicon carbide high and low voltage integrated device includes:
an isolation structure, wherein the isolation structure includes an N-type substrate 110, an N-type drift region 120 is arranged on the N-type substrate 110, a first isolation trench 23144 in which an oxide is deposited and a second isolation trench 12144 in which the oxide is deposited are arranged on the N-type drift region 120 to form a high-voltage region 10, a low-voltage region 20 and a level shift region 30, a second P-type doped region 122 is arranged at the bottom of the low-voltage region 20 and the bottom of the level shift region 30, a second N-type doped region 20132 is arranged on the second P-type doped region 122 in the low-voltage region 20, and back-to-back PN junctions are formed by the N-type drift region 120, the second P-type doped region 122 in the low-voltage region 20, and the second N-type doped region 20132;
a power DMOS device 1, is arranged in the high voltage region 10, low-voltage devices are arranged in the low-voltage region 20, and a high-voltage LDMOS device 5 is arranged in the level shift region 30;
a sixth N-type heavily doped region 201383 is arranged on the second N-type doped region 20132, a third epitaxial layer 30130 is arranged on the second P-type doped region 122 in the level shift region 30, a third N-type doped region 30132 is arranged on the third epitaxial layer 30130, a seventh N-type heavily doped region 501381 used as a drain 50D of the high-voltage LDMOS device 5 is arranged on the third N-type doped region 30132, and the sixth N-type heavily doped region 201383 is connected to the seventh N-type heavily doped region 501381 by means of a fifth drain metal electrode 501522 to control a potential of the second N-type doped region 20132.

In this embodiment:

The low-voltage devices include a low-voltage PMOS device 2, a low-voltage NMOS device 3 and a low-voltage JFET device 4.

The low-voltage PMOS device 2 includes a second P-type heavily doped region 201361, a third P-type heavily doped region 201362 and a second N-type heavily doped region 20138 which are arranged on the second N-type doped region 20132, a second source metal electrode 201521 is connected to the second N-type heavily doped region 20138 and the third P-type heavily doped region 201362 and forms a source 20S of the low-voltage PMOS device 2, a second drain metal electrode 201522 is connected to the second P-type heavily doped region 201361 and forms a drain 20D of the low-voltage PMOS device 2, an interlayer dielectric 140 is arranged between the second N-type doped region 20132, the second N-type heavily doped region 20138, the second P-type heavily doped region 201361 and the third P-type heavily doped region 201362 and the second source metal electrode 201521 and the second drain metal electrode 201522, a second planar gate-oxide dielectric 20146 is arranged on the second N-type doped region 20132 between the source 20S and the drain 20D of the low-voltage PMOS device 2, and a second polysilicon gate 20147 is arranged on the second planar gate-oxide dielectric 20146 and used as a gate 20G of the low-voltage PMOS device 2.

A third P-type doped region 30134 is arranged on the second N-type doped region 20132, the low-voltage NMOS device 3 is arranged in the third P-type doped region 30134 and includes a third N-type heavily doped region 301381, a fourth N-type heavily doped region 301382 and a fourth P-type heavily doped region 30136 which are arranged on the third P-type doped region 30134, the interlayer dielectric 140 is arranged on the third P-type doped region 30134, the third N-type heavily doped region 301381, the fourth N-type heavily doped region 301382 and the fourth P-type heavily doped region 30136, a third source metal electrode 301521 and a third drain metal electrode 301522 are arranged on the interlayer dielectric 140, the third source metal electrode 301521 is connected to the fourth P-type heavily doped region 30136 and the fourth N-type heavily doped region 301382 and forms a source 30S of the low-voltage NMOS device 3, the third drain metal electrode 301522 is connected to the third N-type heavily doped region 301381 and forms a drain 30D of the low-voltage NMOS device 3, a third planar gate-oxide dielectric 30146 is arranged on the interlayer dielectric 140, and a third polysilicon gate 30147 is arranged on the third planar gate-oxide dielectric 30146 and forms a gate 20G of the low-voltage NMOS device 3.

A fourth P-type doped region 40134 is arranged on the second N-type doped region 20132, the low-voltage JFET device 4 is arranged in the fourth P-type doped region 40134 and includes a fifth P-type heavily doped region 401361, a sixth P-type heavily doped region 401362 and a fifth N-type heavily doped region 40138 which are arranged on the fourth P-type doped region 40134, the interlayer dielectric 140 is arranged on the fourth P-type doped region 40134, the fifth P-type heavily doped region 401361, the sixth P-type heavily doped region 401362 and the fifth N-type heavily doped region 40138, a fourth source metal electrode 401521, a fourth drain metal electrode 401522 and a first gate metal electrode 401523 are arranged on the interlayer dielectric 140, the fourth source metal electrode 401521 is connected to the sixth P-type heavily doped region 401362 and forms a source 40S of the low-voltage JFET device 4, the fourth drain metal electrode 401522 is connected to the fifth P-type heavily doped region 401361 and forms a drain 40D of the low-voltage JFET device 4, and the first gate metal electrode 401523 is connected to the fifth N-type heavily doped region 40138 and forms a gate 40G of the low-voltage JFET device 4.

The power DMOS device 1 includes a first P-type doped region 10126 arranged on the N-type drift region 120 in the high-voltage region 10, and first N-type doped regions 10124 are arranged on two sides of the first P-type doped region 10126; a first epitaxial layer 10130 is arranged on the first N-type doped regions 10124, a first P-type heavily doped region 10136 is arranged on the first epitaxial layer 10130, a first polysilicon gate 10147 wrapped by a first trench gate-oxide dielectric 10146 is arranged on the first P-type doped region 10126 and form a gate 10G of the power DMOS device 1, first N-type heavily doped regions 10138 are arranged on two sides of the first trench gate-oxide dielectric 10146 respectively and located in the first epitaxial layer 10130, the interlayer dielectric 140 is arranged on the first trench gate-oxide dielectric 10146, the first polysilicon gate 10147, the first P-type heavily doped region 10136 and the first N-type heavily doped regions 10138, a first source metal electrode 101521 is arranged on the interlayer dielectric 140, the first source metal electrode 101521 is connected to the first P-type heavily doped region 10136 and the first N-type heavily doped regions 10138 and forms a source 10S of the DMOS device 1, and a first drain metal electrode 101522 is arranged on the N-type substrate 110 and used as a drain 10D of the power DMOS device 1.

The high-voltage LDMOS device 5 further includes a seventh P-type heavily doped region 50136 and an eighth N-type heavily doped region 501382 which are arranged in the third epitaxial layer 30130 in the level shift region 30, the interlayer dielectric 140 is arranged on the third epitaxial layer 30130, the seventh P-type heavily doped region 50136, the eighth N-type heavily doped region 501382, the third N-type doped region 30132 and the seventh N-type heavily doped region 501381, a fifth source metal electrode 501521 is arranged on the interlayer dielectric 140, the fifth source metal electrode 501521 is connected to the seventh P-type heavily doped region 50136 and the eighth N-type heavily doped region 501382 and forms a source 50S of the high-voltage LDMOS device 5, a fourth planar gate-oxide dielectric 50146 is arranged between the interlayer dielectric 140 and the third epitaxial layer 30130 and located between the eighth N-type heavily doped region 501382 and the third N-type doped region 30132, and a fourth polysilicon gate 50147 is arranged on the fourth planar gate-oxide dielectric 50146 and used as a gate 50G of the high-voltage LDMOS device 5.

In this embodiment, the power DMOS device 1 is used as a power device; the low-voltage PMOS device 2, the low-voltage NMOS device 3 and the low-voltage JFET device 4 form a drive circuit or protection circuit of a half-bridge low-side transistor; the high-voltage LDMOS device 5 forms a level shift circuit. In a case where the silicon carbide high and low voltage integrated device is used as the drive circuit of the half-bridge low-side transistor, the potential of the epitaxial layer in the low-voltage region is 0. In a case where the silicon carbide high and low voltage integrated device is used as the drive circuit of the half-bridge high-side transistor, the LDMOS device is turned off to increase the potential of the epitaxial layer in the low-voltage region, the first P-type doped region 10126 arranged below the gate 10G of the DMOS device can control an electric field in a gate region to prevent pre-breakdown, and the first N-type doped regions 10124 are arranged in a drift region of the DMOS device to reduce the on-resistance of the device.

### Embodiment 3

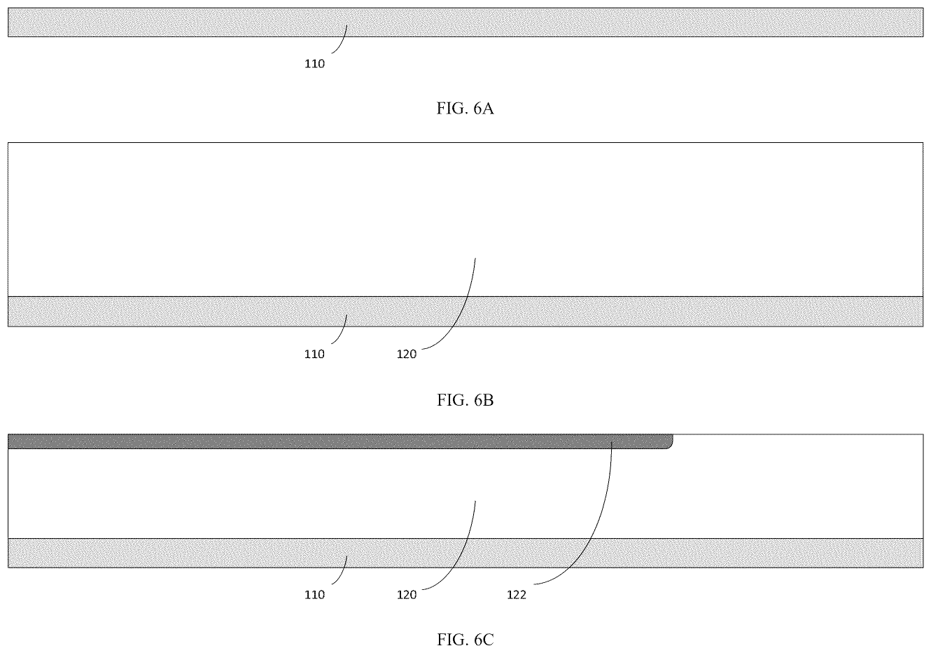

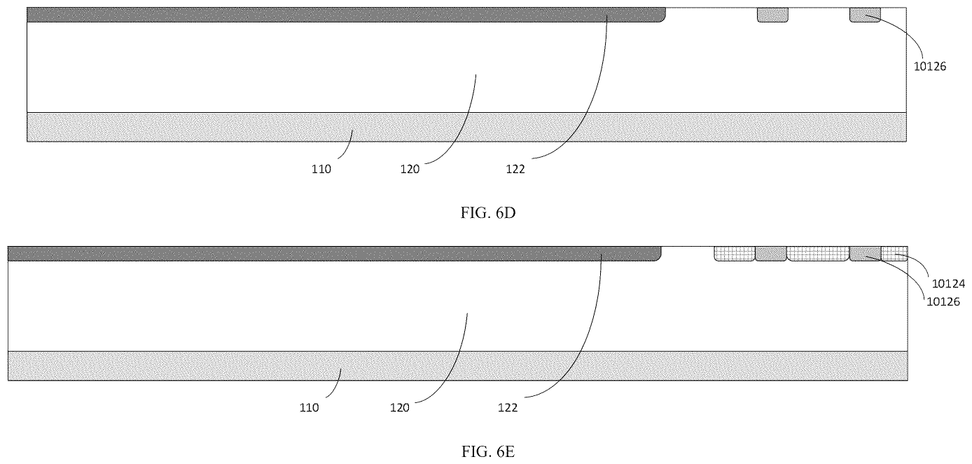

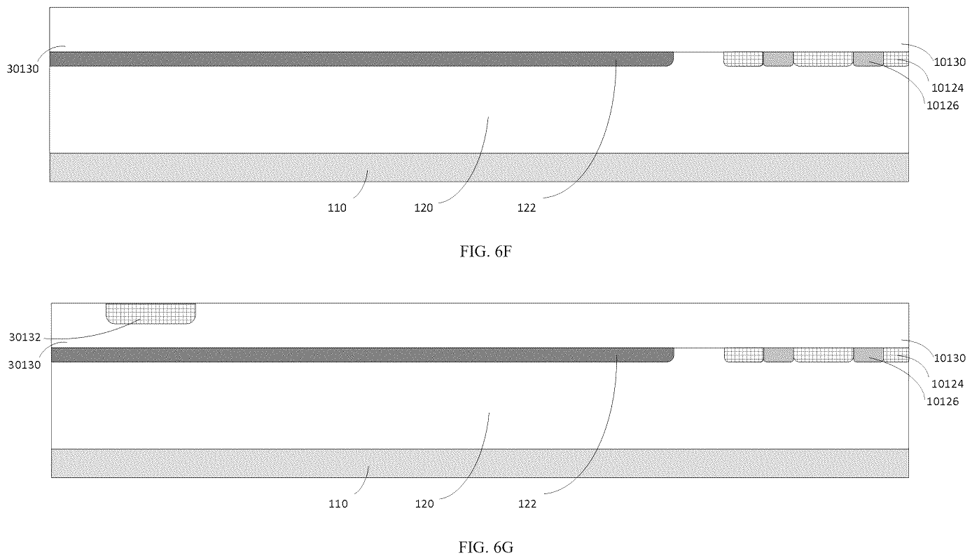

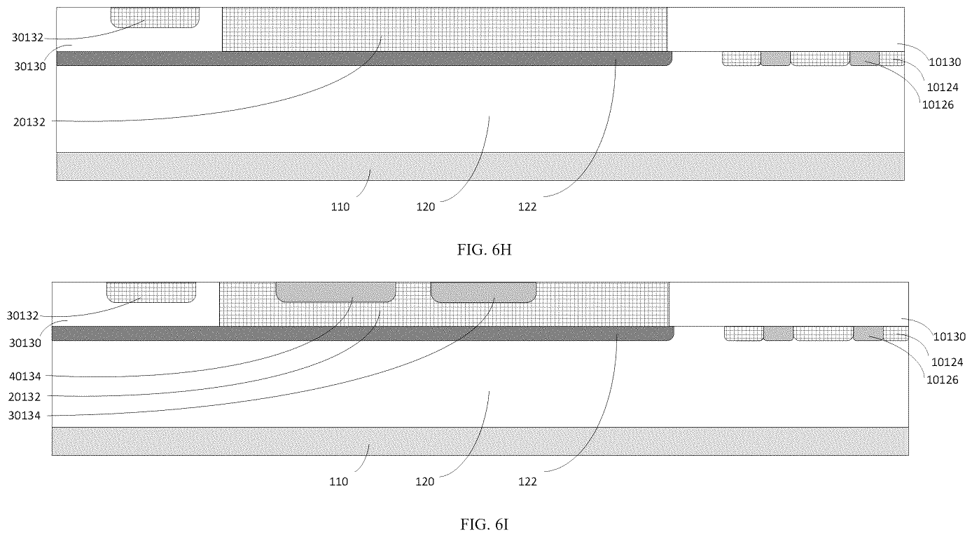

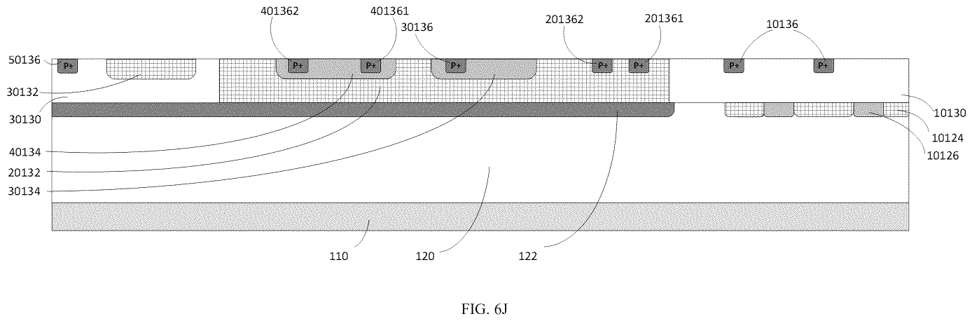

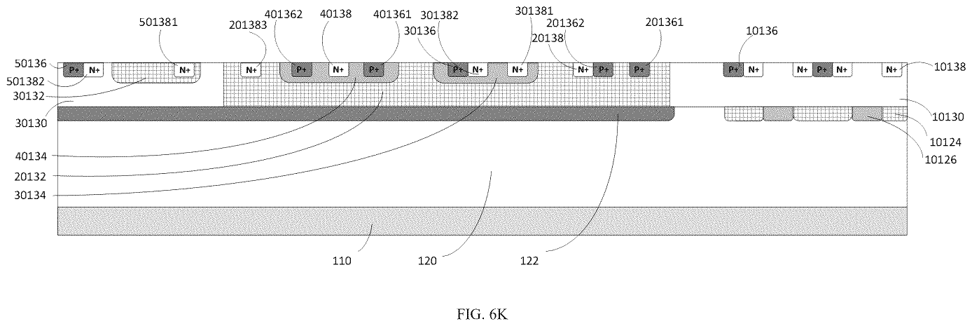

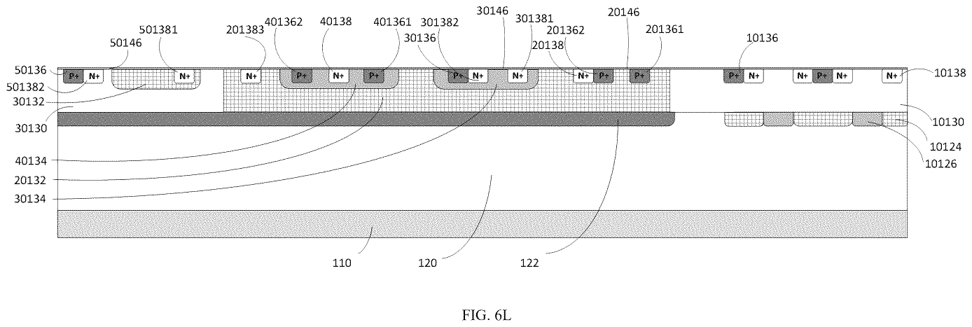

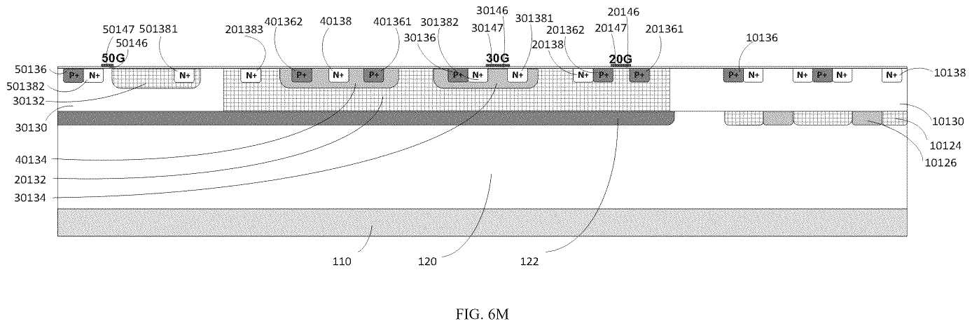

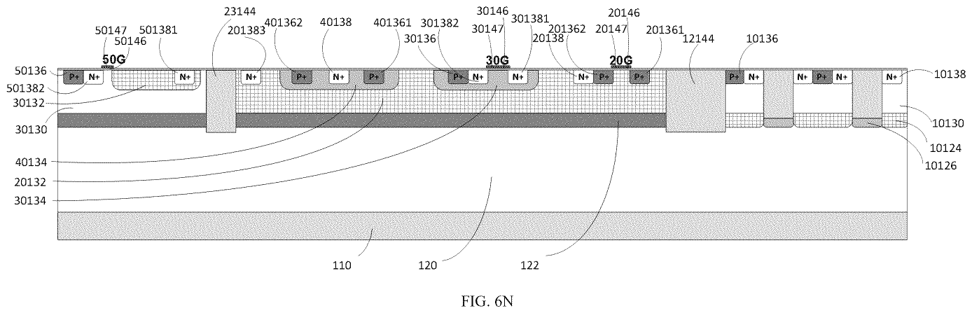

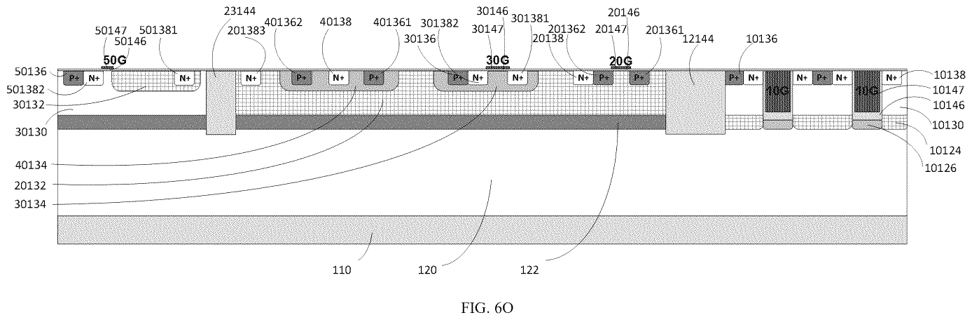

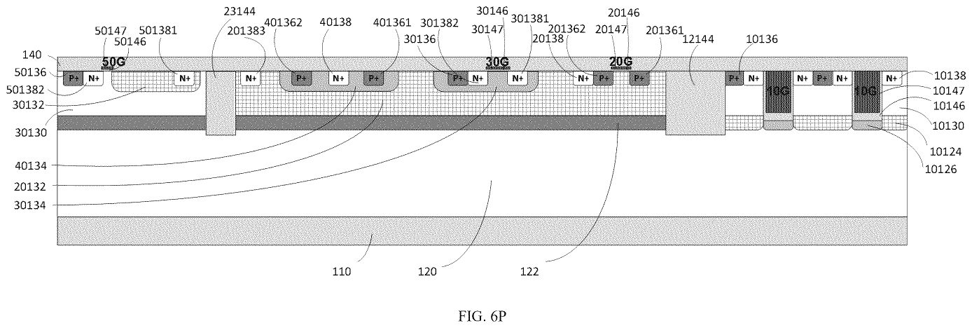

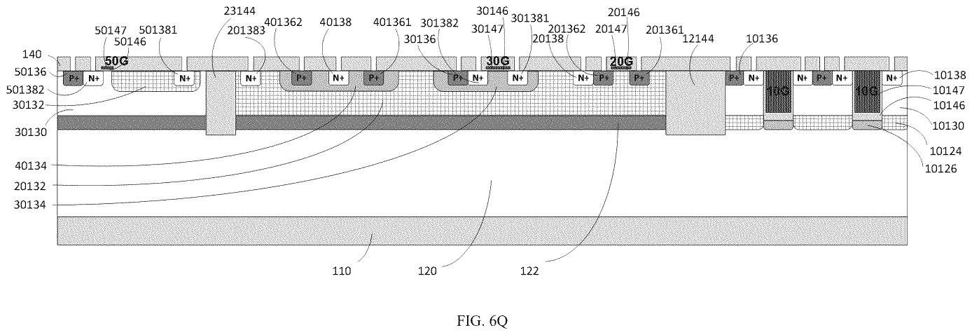

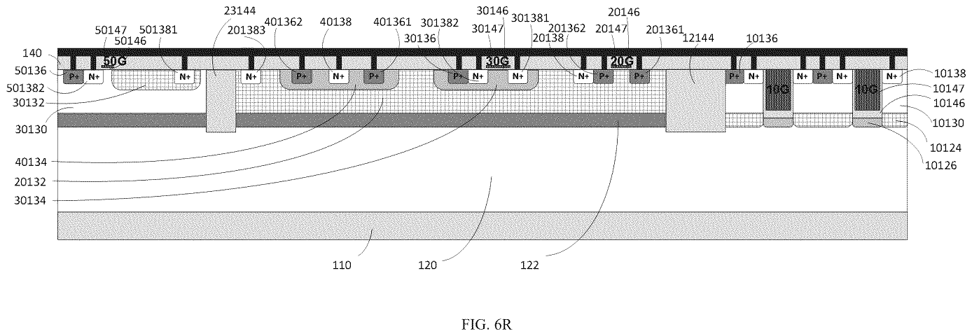

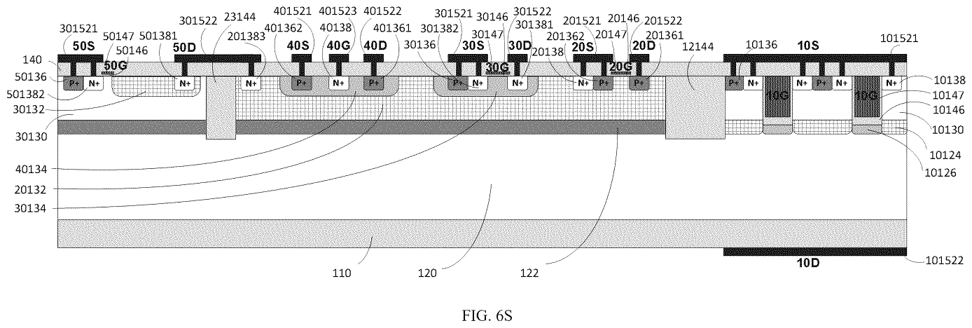

A preparation method for an N epitaxy-based silicon carbide high and low voltage integrated device includes the following steps:
a silicon carbide N-type substrate 110 is acquired;
an N-type drift region 120 is epitaxially grown on one surface of the N-type substrate 110; four times of ion implantation are performed on the N-type drift region 120 to form a second P-type doped region 122, wherein dosages in the four times of ion implantation are 4 E12 cm⁻², 6 E12 cm⁻², 1 E13 cm⁻² and 1.2 E13 cm⁻², respectively, energy in the four times of ion implantation is 80 keV, 120 keV, 200 keV and 280 keV, respectively, and the type of ions is Al; three times of ion implantation are performed and a first P-type doped region 10126 and first N-type doped regions 10124 are formed respectively, wherein dosages in the three times of ion implantation are 1 E12 cm⁻², 1.2 E12 cm⁻² and 1.5 E12 cm⁻², respectively, energy in the three times of ion implantation is 80 keV, 100 keV and 120 keV, respectively, and the types of ions are Al and N, respectively;
a P-type epitaxial layer is grown on surfaces of the second P-type doped region 122, part of the N-type drift region 120, the first P-type doped region 10126 and the first N-type doped regions 10124, and a first epitaxial layer 10130 and a third epitaxial layer 30130 are formed;
four times of ion implantation are performed on the third epitaxial layer 30130 above the second P-type doped region 122 to form a third N-type doped region 30132, wherein dosages in the four times of ion implantation are 1 E12 cm⁻², 1.2 E12 cm⁻², 1.5 E12 cm⁻² and 2 E12 cm⁻², respectively, energy in the four times of ion implantation is 80 keV, 120 keV, 180 keV and 240 keV, respectively, and the type of ions is N; sixth times of ion implantation are performed on the third epitaxial layer 30130 above the second P-type doped region 122 to form a second N-type doped region 20132, wherein dosages in the six times of ion implantation are 1 E12 cm⁻², 1.2 E12 cm⁻², 1.6 E13 cm⁻², 2.0 E12 cm⁻², 2.4 E12 cm⁻²and 3 E12 cm⁻², respectively, energy in the six times of ion implantation is 80 keV, 150 keV, 200 keV, 30 0keV, 400 keV and 500 keV, respectively, and the type of ions is N; then, four times of ion implantation are performed on the third N-type doped region 30132 to form a third P-type doped region 30134 and a fourth P-type doped region 40134, wherein dosages in the four times of ion implantation are 1 E12 cm⁻², 1.2 E12 cm⁻², 1.5 E12 cm⁻² and 2 E12 cm⁻², respectively, energy in the four times of ion implantation is 80 keV, 120 keV, 180 keV and 240 keV, respectively, and the type of ions is Al;
two times of ion implantation are performed on the first epitaxial layer 10130 above the first N-type doped regions 10124, the second N-type doped region 20132, the third P-type doped region 30134, the fourth P-type doped region 40134 and the third epitaxial layer 30130 to form a first P-type heavily doped region 10136, a second P-type heavily doped region 201361, a third P-type heavily doped region 201362, a fourth P-type heavily doped region 30136, a fifth P-type heavily doped region 401361, a sixth P-type heavily doped region 401362 and a seventh P-type heavily doped region 50136, wherein dosages in the two times of ion implantation are 4 E14 cm⁻² and 5 E14 cm⁻², respectively, energy in the two times of ion implantation is 80 keV and 100 keV, respectively, and the type of ions is Al;
two times of ion implantation are performed to form first N-type heavily doped regions 10138, the number of which is twice that of the first P-type heavily doped region 10136, in the first epitaxial layer 10130 above the first N-type doped regions 10124, form a second N-type heavily doped region 20138 and a sixth N-type heavily doped region 201383 in the second N-type doped region 20132, form a third N-type heavily doped region 301381 and a fourth N-type heavily doped region 301382 in the third P-type doped region 30134, form a fifth N-type heavily doped region 40138 in the fourth P-type doped region 40134, form a seventh N-type heavily doped region 501381 in the third N-type doped region 30132, and form an eighth N-type heavily doped region 501382 in the third epitaxial layer 30130, wherein dosages in the two times of ion implantation are 4 E14 cm⁻² and 5 E14 cm⁻², respectively, energy in the two times of ion implantation is 80 keV and 100 keV, respectively, and the type of ions is N;
high-temperature annealing is performed at 1650° C. for 30 min, then water vapor is introduced at 1200° C. for 40 min for oxidation, a gate-oxide dielectric is grown on a surface of a current local device structure, the gate-oxide dielectric above the second N-type doped region 20132 between the second P-type heavily doped region 201361 and the third P-type heavily doped region 201362 is taken as a second planar gate-oxide dielectric 20146, the gate-oxide dielectric above the third P-type doped region 30134 between the third N-type heavily doped region 301381 and the fourth N-type heavily doped region 301382 is taken as a third planar gate-oxide dielectric 30146, and the gate-oxide dielectric above the third epitaxial layer 30130 between the third N-type doped region 30132 and the eighth N-type heavily doped region 501382 is taken as a fourth planar gate-oxide dielectric 50146, wherein the surface of the current local device structure refers to a surface of a device structure shown in FIG. 6K;
a second polysilicon gate 20147, a third polysilicon gate 30147 and a fourth polysilicon gate 50147 are respectively deposited on the second planar gate-oxide dielectric 20146, the third planar gate-oxide dielectric 30146 and the fourth planar gate-oxide dielectric 50146;
trenches are respectively etched between the first epitaxial layer 10130 and the second N-type doped region 20132, between the second N-type doped region 20132 and the third epitaxial layer 30130, and in the first epitaxial layer 10130 above the first P-type doped region 10126 and an oxide is deposited to form a first isolation trench 23144, a second isolation trench 12144 and an oxide trench, etching is performed in the oxide trench, a first trench gate-oxide dielectric 10146 is formed, and polysilicon is deposited in the first trench gate-oxide dielectric 10146 to form a first polysilicon gate 10147, wherein the number of the first trench gate-oxide dielectrics 10146 is the same as the number of the first P-type heavily doped regions 10136 and may be one or more, and two first trench gate-oxide dielectrics 10146 and two first P-type heavily doped regions 10136 are shown in the drawings of the invention; and
an oxide layer is deposited on a device surface in a current state to form an interlayer dielectric 140, through-holes are etched in the interlayer dielectric 140, a metal layer is deposited, and then, the metal layer is etched to form a first source metal electrode 101521, a second drain metal electrode 201522, a second source metal electrode 201521, a third drain metal electrode 301522, a third source metal electrode 301521, a fourth drain metal electrode 401522, a first gate metal electrode 401523, a fourth source metal electrode 401521, a fifth drain metal electrode 501522 and a fifth source metal electrode 501521; metal is deposited in a high-voltage region 10 on the other surface of the N-type substrate 110, and a first drain metal electrode 101522 is formed, wherein the “device surface in the current state” refers to a device surface shown in FIG. 6O.

In this embodiment, the first P-type doped region 10126 is formed by three times of ion implantation, wherein the doping concentration is about 1 E15 cm⁻³, and the type of implanted ions is Al; the second P-type doped region 122 is formed by four times of ion implantation, wherein the doping concentration is about 1.1 E17 cm⁻², and the type of implanted ions is Al; the third P-type doped region 30134 and the fourth P-type doped region 40134 are formed by four times of ion implantation, wherein the doping concentration is about 1 E16 cm⁻³, and the type of implanted ions is Al; the first N-type doped regions 10124 are formed by three times of ion implantation, wherein the doping concentration is about 1 E17 cm⁻³, and the type of implanted ions is N; the second N-type doped region 20132 is formed by sixth times of ion implantation, wherein the doping concentration is about 1 E16 cm⁻³, and the type of implanted ions is N; the third N-type doped region 30132 is formed by four times of ion implantation, wherein the doping concentration is about 1 E16 cm⁻³, and the type of implanted ions is N; the first P-type heavily doped region 10136, the second P-type heavily doped region 201361, the third P-type heavily doped region 201362, the fourth P-type heavily doped region 30136, the fifth P-type heavily doped region 401361, the sixth P-type heavily doped region 401362 and the seventh P-type heavily doped region 50136 are formed by two times of ion implantation, wherein the doping concentration is about 1 E19 cm⁻³, and the type of implanted ions is Al; the first N-type heavily doped regions 10138, the second N-type heavily doped region 20138, the third N-type heavily doped region 301381, the fourth N-type heavily doped region 301382, the fifth N-type heavily doped region 40138, the sixth N-type heavily doped region 201383 and the seventh N-type heavily doped region 501381 are formed by two times of ion implantation, wherein the doping concentration is about 1 E19 cm⁻³, and the type of implanted ions is N.

In this embodiment, in the process of etching the first isolation trench 23144 and the second isolation trench 12144, the trenches below the second P-type doped region 122 are etched by enlarging a mask window.

In this embodiment, the doping concentration of the second P-type doped region 122 at the bottom of the low-voltage region 20 and the bottom of the level shift region 30 should be greater than 1 E17 cm⁻³ such that the PN junction formed by the second P-type doped region 122 is able to withstand a 1.2 kV voltage.

In this embodiment, the doping concentration of the N-type drift region 120 is less than the doping concentration of the substrate 110.

The specific implementation of the invention is described in further detail below with reference to the accompanying drawings.

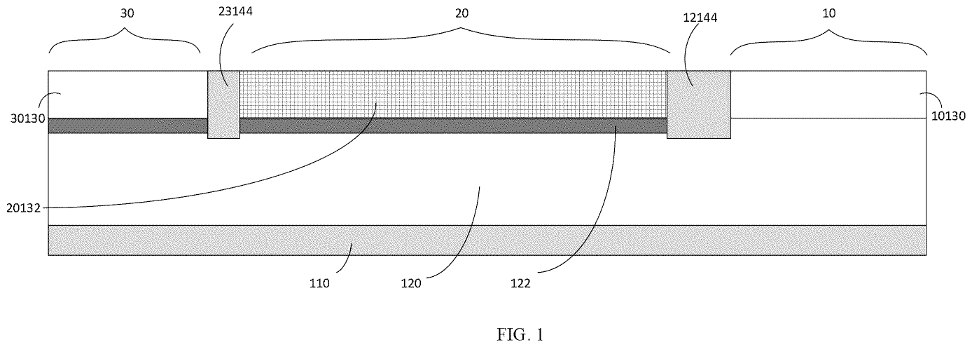

FIG. 1 is a schematic diagram of a high and low voltage isolation structure for an N epitaxy-based silicon carbide high and low voltage integrated device according to one embodiment of the application. Referring to FIG. 1, an N-type drift region 120 is arranged on an N-type substrate 110, a first isolation trench 23144 in which an oxide is deposited and a second isolation trench 12144 in which the oxide is deposited are arranged on the N-type drift region 120 to form a high-voltage region 10, a low-voltage region 20 and a level shift region 30, a second P-type doped region 122 is arranged at the bottom of the low-voltage region 20 and the bottom of the level shift region 30, a second N-type doped region 20132 is arranged on the second P-type doped region 122 in the low-voltage region 20, and back-to-back PN junctions are formed by the N-type drift region 120, the second P-type doped region 122 in the low-voltage region 20, and the second N-type doped region 20132.

In the embodiment shown in FIG. 1, the first isolation trench 23144 and the second isolation trench 12144 extend deep below the second P-type doped region 122, such that current interference between the high-voltage region 10 and the low-voltage region 20 and between the low-voltage region 20 and the level shift region 30 in an epitaxial layer can be completely prevented.

In the embodiment shown in FIG. 1, a reverse-biased PN junction formed by the second P-type doped region 122 and the drift region 120 can completely prevent the influence of the high-voltage region 10 on the potential of the substrate in the low-voltage region 20; a reverse-biased PN junction formed by the second P-type doped region 122 and the second N-type doped region 20132 on the epitaxial layer can eliminate the influence of the potential of the substrate in the low-voltage region 20 on the high-voltage region 10. The doping concentration of the second P-type doped region 122 in the drift region is not less than 1 E17 cm⁻³, such that the second P-type doped region 122 can withstand a high voltage of 1.2 kV.

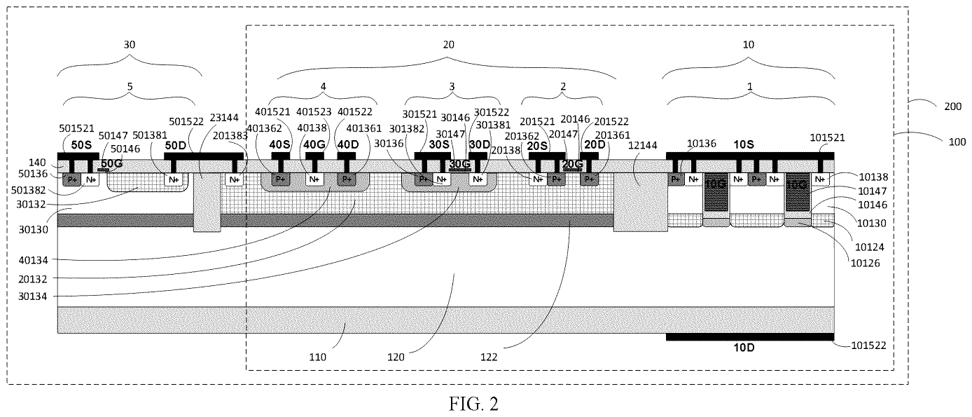

FIG. 2 is a schematic structural diagram of a silicon carbide high and low voltage integrated device according to one embodiment of the application. Referring to FIG. 2, the silicon carbide high and low voltage integrated device includes an N-type substrate 110, wherein an N-type drift region 120 is arranged on the N-type substrate 110, a first isolation trench 23144 in which an oxide is deposited and a second isolation trench 12144 in which the oxide is deposited are arranged on the N-type drift region 120 to form a high-voltage region 10, a low-voltage region 20 and a level shift region 30, a second P-type doped region 122 is arranged at the bottom of the low-voltage region 20 and the bottom of the level shift region 30, a second N-type doped region 20132 is arranged on the second P-type doped region 122 in the low-voltage region 20, and back-to-back PN junctions are formed by the N-type drift region 120, the second P-type doped region 122 in the low-voltage region 20, and the second N-type doped region 20132; a power DMOS device 1 is arranged in the high-voltage region 10, low-voltage devices are arranged in the low-voltage region 20, and a high-voltage LDMOS device S is arranged in the level shift region 30.

The low-voltage devices include a low-voltage PMOS device 2, a low-voltage NMOS device 3 and a low-voltage JFET device 4. The low-voltage PMOS device 2 includes the second P-type doped region 122 arranged at the bottom of the low-voltage region 30, a second N-type doped region 20132 is arranged on the second P-type doped region 122, a second N-type heavily doped region 20138, a second P-type heavily doped region 201361 and a third P-type heavily doped region 201362 are arranged on the second N-type doped region 20132, an interlayer dielectric 140 is arranged on the second N-type doped region 20132, the second N-type heavily doped region 20138, the second P-type heavily doped region 201361 and the third P-type heavily doped region 201362, a second source metal electrode 201521 and a second drain metal electrode 201522 are arranged on the interlayer dielectric 140, the second source metal electrode 201521 is connected to the second N-type heavily doped region 20138 and the third P-type heavily doped region 201362 and forms a source 20S of the low-voltage PMOS device 2, the second drain metal electrode 201522 is connected to the second P-type heavily doped region 201361 and forms a drain 20D of the low-voltage PMOS device 2, a second planar gate-oxide dielectric 20146 is arranged on the interlayer dielectric 140, and a second polysilicon gate 20147 is arranged on the second planar gate-oxide dielectric 20146 and is a gate 20G of the low-voltage PMOS device 2; the low-voltage NMOS device 3 includes the second P-type doped region 122 arranged at the bottom of the low-voltage region 30, the second N-type doped region 20132 is arranged on the second P-type doped region 122, a third P-type doped region 30134 is arranged on the second N-type doped region 20132, a third N-type heavily doped region 301381, a fourth N-type heavily doped region 301382 and a fourth P-type heavily doped region 30136 are arranged on the third P-type doped region 30134, the interlayer dielectric 140 is arranged on the third P-type doped region 30134, the third N-type heavily doped region 301381, the fourth N-type heavily doped region 301382 and the fourth P-type heavily doped region 30136, a third source metal electrode 301521 and a third drain metal electrode 301522 are arranged on the interlayer dielectric 140, the third source metal electrode 301521 is connected to the fourth P-type heavily doped region 30136 and the fourth N-type heavily doped region 301382 and forms a source 30S of the low-voltage NMOS device 3, the third drain metal electrode 301522 is connected to the third N-type heavily doped region 301381 and forms a drain 30D of the low-voltage NMOS device 3, a third planar gate-oxide dielectric 30146 is arranged on the interlayer dielectric 140, and a third polysilicon gate 30147 is arranged on the third planar gate-oxide dielectric 30146 and is a gate 30G of the low-voltage NMOS device 3; the low-voltage JFET device 4 includes the second P-type doped region 122 arranged at the bottom of the low-voltage region 30, the second N-type doped region 20132 is arranged on the second P-type doped region 122, a fourth P-type doped region 40134 is arranged on the second N-type doped region 20132, a fifth P-type heavily doped region 401361, a sixth P-type heavily doped region 401362 and a fifth N-type heavily doped region 40138 are arranged on the fourth P-type doped region 40134, the interlayer dielectric 140 is arranged on the fourth P-type doped region 40134, the fifth P-type heavily doped region 401361, the sixth P-type heavily doped region 401362 and the fifth N-type heavily doped region 40138, a fourth source metal electrode 401521, a fourth drain metal electrode 401522 and a first gate metal electrode 401523 are arranged on the interlayer dielectric 140, the fourth source metal electrode 401521 is connected to the sixth P-type heavily doped region 401362 and forms a source 40S of the low-voltage JFET device 4, the fourth drain metal electrode 401522 is connected to the fifth P-type heavily doped region 401361 and forms a drain 40D of the low-voltage JFET device 4, and the first gate metal electrode 40152 is connected to the fifth N-type heavily doped region 40138 and forms a gate 40G of the low-voltage JFET device 4; a sixth N-type heavily doped region 201383 is arranged on the second N-type doped region 20132.

The power DMOS device 1 includes first N-type doped regions 10124 and a first P-type doped region 10126 which are arranged on the N-type drift region 120, the first N-type doped regions 10124 and the first P-type doped region 10126 are distributed alternately, a first epitaxial layer 10130 is arranged on the first N-type doped regions 10124, a first polysilicon gate 10147 wrapped by a first trench gate-oxide dielectric 10146 is arranged on the first P-type doped region 10126 and forms a gate 10G of the power DMOS device 1, a first P-type heavily doped region 10136 and first N-type heavily doped regions 10138 are arranged on an outer side of the first polysilicon gate 10147 and located on the first epitaxial layer 10130, the interlayer dielectric 140 is arranged on the first trench gate-oxide dielectric 10146, the first polysilicon gate 10147, the first P-type heavily doped region 10136 and the first N-type heavily doped regions 10138, a first source metal electrode 101521 is arranged on the interlayer dielectric 140, the first source metal electrode 101521 is connected to the first P-type heavily doped region 10136 and the first N-type heavily doped regions 10138 to form a source 10S of the power DMOS device 1, and a drain 10D of the DMOS device 1 is a first drain metal electrode 101522 arranged on the N-type substrate 110.

The high-voltage LDMOS device 5 includes the second P-type doped region 122 arranged at the bottom of the level shift region 30, a third epitaxial layer 30130 is arranged on the second P-type doped region 122, a seventh P-type heavily doped region 50136, an eighth N-type heavily doped region 501382 and the third N-type doped region 30132 are arranged on the third epitaxial layer 30130, a seventh N-type heavily doped region 501381 is arranged on the third N-type doped region 30132, the interlayer dielectric 140 is arranged on the third epitaxial layer 30130, the seventh P-type heavily doped region 50136, the eighth N-type heavily doped region 501382, the third N-type doped region 30132 and the seventh N-type heavily doped region 501381, a fifth source metal electrode 501521 and a fifth drain metal electrode 501522 are arranged on the interlayer dielectric 140, the fifth source metal electrode 501521 is connected to the seventh P-type heavily doped region 50136 and the eighth N-type heavily doped region 501382 and forms a source 50S of the high-voltage LDMOS device 5, the fifth drain metal electrode 501522 is connected to the seventh N-type heavily doped region 501381 and forms a drain 50D of the high-voltage LDMOS device 5, a fourth planar gate-oxide dielectric 50146 is arranged on the interlayer dielectric 140, and a fourth polysilicon gate 50147 is arranged on the fourth planar gate-oxide dielectric 50146 and is a gate 50G of the high-voltage LDMOS device 5. The fifth drain metal electrode 501522 is connected to the sixth N-type heavily doped region 201383 to control the potential of the second N-type doped region 20132.

Silicon carbide power devices have a broad application prospect in high-temperature and high-irradiation fields such as the aerospace field, the new energy vehicle field, the energy exploration drilling field and the nuclear power field because of their material advantages. However, existing drive circuits and protection circuits used together with silicon carbide power devices are still based on silicon and have poor high-temperature resistance and irradiation resistance, severely limiting the application range of the silicon carbide power devices.

The silicon carbide high and low voltage integrated device provided by the application eliminates the interference between high and low voltages by means of the isolation structure and integrates high-voltage devices and low-voltage devices on the same substrate, The high-voltage DMOS device works as a power device, and the low-voltage NMOS, the low-voltage PMOS and the low-voltage JFET device form a half-bridge drive circuit, protection circuit, or the like. A reverse-biased PN junction formed by the second P-type doped region and the N-type drift region in the drift region can completely prevent the influence of a high voltage of the drain of the power DMOS device on the potential of the substrate of the low-voltage devices. A reverse-biased PN junction formed by the second N-type doped region on the epitaxial layer and the second P-type doped region above the drift region eliminates the influence of the potential of the substrate of the drive circuit on the potential of the power DMOS device. The second isolation trench is arranged between the high-voltage region and the low-voltage region, extends deep below the second P-type doped region, and thus can completely prevent transverse current interference between the low-voltage devices and the high-voltage devices. In a case where the silicon carbide high and low voltage integrated device is used as a gate drive circuit of a half-bridge low-side transistor, the potential of the epitaxial layer in the low-voltage region is 0. In a case where the silicon carbide high and low voltage integrated device is used as a gate drive circuit of a half-bridge high-side transistor, the LDMOS device is turned off to increase the potential of the epitaxial layer in the low-voltage region.

In an embodiment shown in FIG. 2, a region 100 is used as a drive circuit of a half-bridge low-side transistor, and a region 200 is used as a drive circuit of a half-bridge high-side transistor.

In the embodiment shown in FIG. 2, the first P-type doped region 10126 below the gate-oxide dielectric 10146 of the DMOS device can control the electric field of a gate region to prevent pre-breakdown. The first N-type doped regions 10124 on the two sides of the first P-type doped region 10126 can reduce the on-resistance of the device.

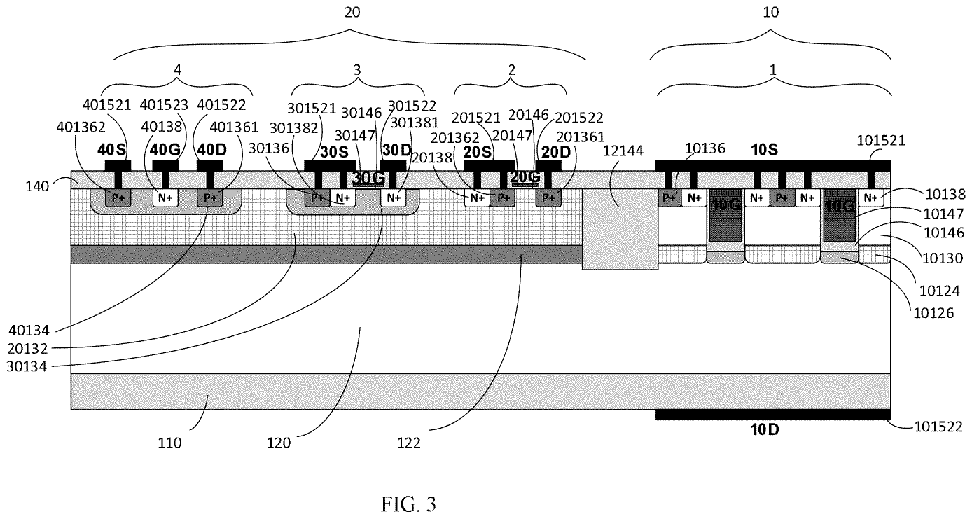

FIG. 3 is a schematic structural diagram of the silicon carbide high and low voltage integrated device used as a drive circuit of a half-bridge low-side transistor according to one embodiment of the application. In this embodiment, the low-voltage devices in the low-voltage region 20 are used as a gate drive circuit, protection circuit or the like of the half-bridge low-side transistor, and the high-voltage DMOS device 1 is used as a power device. Specifically, the potential of the second N-type doped region 20132 in the low-voltage region is 0.

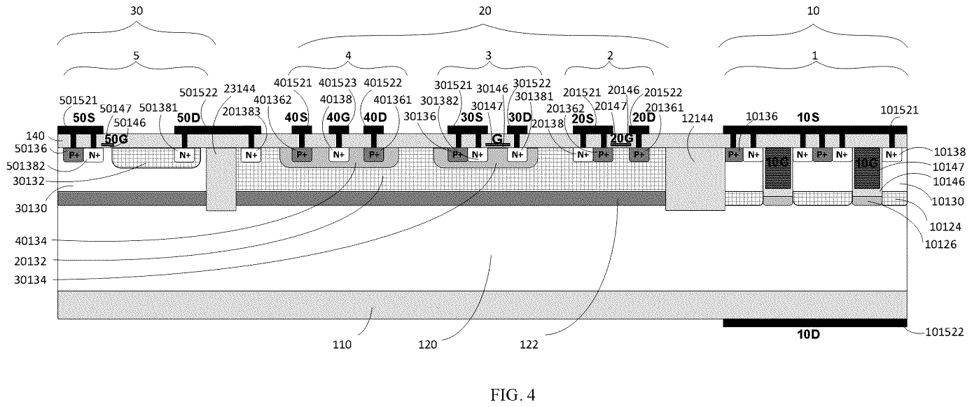

FIG. 4 is a schematic structural diagram of the silicon carbide high and low voltage integrated device used as a drive circuit of a half-bridge high-side transistor according to one embodiment of the application. In this embodiment, the low-voltage devices in the low-voltage region 20 are used as a gate drive circuit, protection circuit or the like of a half-bridge high-side transistor, the high-voltage DMOS device 1 is used as a power device, and the LDMOS device 5 is used to increase the potential of the epitaxial layer. Specifically, when the LDMOS device 5 is in an off state, the potential of the drain 50D of the LDMOS device 5 is 1.2 kV, and the potential of the second N-type doped region 20132 in the low-voltage region is also increased to 1.2 kV.

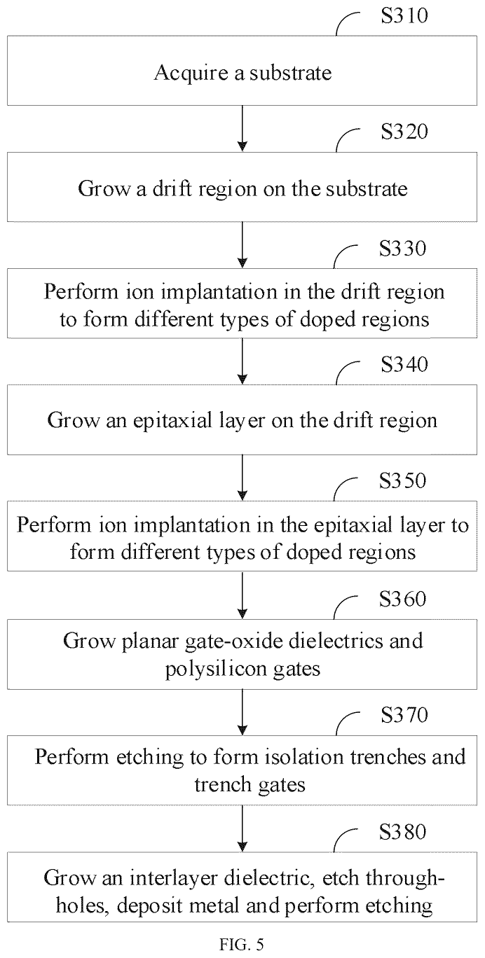

Correspondingly, the application provides a preparation method for an N epitaxy-based high and low voltage integrated device, which may be used for preparing the silicon carbide high and low voltage integrated circuit in any one of the above embodiments. FIG. 5 is a flow diagram of the preparation method for a silicon carbide high and low voltage integrated circuit according to one embodiment of the application. The preparation method includes the following steps:
S310, a substrate is acquired.

An N-type silicon carbide substrate is acquired.
S320, a drift region is grown on the substrate.

In one embodiment of the application, the drift region 120 is N-type silicon carbide.

In one embodiment of the application, the doping concentration of the drift region 120 is less than the doping concentration of the substrate 110.
S330, ion implantation is performed in the drift region to form different types of doped regions.

Multiple doped regions of different types are formed in the drift region by multiple times of ion implantation.

In one embodiment of the application, a first P-type doped region 10126, a second P-type doped region 122 and first N-type doped regions 10124 are formed by ion implantation.
S340, epitaxial layers are grown on the drift region.

In one embodiment of the application, a first epitaxial layer 10130 and a third epitaxial layer 30130 are P-type silicon carbide.
S350, ion implantation is performed in the epitaxial layers to form different types of doped regions.

In one embodiment of the application, a second N-type doped region 20132, a third N-type doped region 30132, a third P-type doped region 30134, a fourth P-typed doped region 40134, a first P-type heavily doped region 10136, a second P-type heavily doped region 201361, a third P-type heavily doped region 201362, a fourth P-type heavily doped region 30136, a fifth P-type heavily doped region 401361, a sixth P-type heavily doped region 401362, a seventh P-type heavily doped region 50136, first N-type heavily doped regions 10138, a second N-type heavily doped region 20138, a third N-type heavily doped region 301381, a fourth N-type heavily doped region 301382, a fifth N-type heavily doped region 40138, a sixth N-type heavily doped region 201383, a seventh N-type heavily doped region 501381 and an eighth heavily doped region 501382 are formed by multiple times of ion implantation, and high-temperature annealing is performed.
S360, planar gate-oxide dielectrics and polysilicon gates are grown.

The planar gate-oxide dielectrics are grown by wet oxidation, and polysilicon is deposited on the gate-oxide dielectrics.

In one embodiment of the application, a second planar gate-oxide dielectric 20146, a third planar gate-oxide dielectric 30146 and a fourth planar gate-oxide dielectric 40146 are grown on the first epitaxial layer 10130, the third epitaxial layer 30130 and the second N-type doped region 20132; a second polysilicon gate 20147, a third polysilicon gate 30147 and a fourth polysilicon gate 40147 are deposited on the planar gate-oxide dielectrics, respectively.
S370, etching is performed to form isolation trenches and trench gates.

In one embodiment of the application, trenches are etched in the first epitaxial layer 10130, the third epitaxial layer 30130 and the second N-type doped region 20132 and an oxide is deposited to form a first isolation trench 23144, a second isolation trench 12144 and an oxide trench; then, etching is performed in the oxide trench to form a first trench gate-oxide dielectric 10146, and polysilicon is deposited in the first trench gate-oxide dielectric 10146 to form a first polysilicon gate 10147.

In one embodiment of the application, trenches with different depths are formed by controlling the mask window. In one embodiment of the application, the first isolation trench 23144 and the second isolation trench 12144 extend deep below the second P-type doped region 122.
S280, an interlayer dielectric is grown, through-holes are etched, metal electrodes are deposited, and etching is performed.

An oxide layer is deposited on the epitaxial layers to form an interlayer dielectric which is distributed all over a device surface, and through-holes are formed in the interlayer dielectric and extend deep into the doped regions on the epitaxial layers. Metal is deposited in the through-holes, and the metal is etched to form segmented metal electrodes.

In one embodiment of the application, an interlayer dielectric 140 is deposited on the second planar gate-oxide dielectric 20146, the third planar gate-oxide dielectric 30146 and the fourth planar gate-oxide dielectric 40146 and distributed all over the device surface, through-holes are etched in the interlayer dielectric 140, metal is deposited in the through-holes in the interlayer dielectric 140, and the metal is etched to form a first source metal electrode 101521, a first drain metal electrode 101522, a second source metal electrode 201521, a second drain metal electrode 201522, a third source metal electrode 301521, a third drain metal electrode 301522, a fourth source metal electrode 401521, a fourth drain metal electrode 401522, a first gate metal electrode 401523, a fifth source metal electrode 501521 and a fifth drain metal electrode 501522.

In one embodiment of the application, the metal electrodes are made from metal and/or alloy.

According to the preparation method for a silicon carbide high and low voltage integrated device, the interference between high and low voltages is eliminated by the isolation structure, and high-voltage devices and low-voltage devices are integrated on the same substrate. The high-voltage DMOS device works as a power device, and the low-voltage NMOS, the low-voltage PMOS and the low-voltage JFET device form a half-bridge drive circuit, protection circuit, or the like. A reverse-biased PN junction formed by the second P-type doped region and the N-type drift region in the drift region can completely prevent the influence of a high voltage of the drain of the power DMOS device on the potential of the substrate of the low-voltage devices. A reverse-biased PN junction formed by the second N-type doped region on the epitaxial layer and the second P-type doped region above the drift region eliminates the influence of the potential of the substrate of the drive circuit on the potential of the power DMOS device. The second isolation trench is arranged between the high-voltage region and the low-voltage region, extends deep below the second P-type doped region, and thus can completely prevent transverse current interference between the low-voltage devices and the high-voltage devices. In a case where the silicon carbide high and low voltage integrated device is used as a gate drive circuit of a half-bridge low-side transistor, the potential of the epitaxial layer in the low-voltage region is 0. In a case where the silicon carbide high and low voltage integrated device is used as a gate drive circuit of a half-bridge high-side transistor, the LDMOS device is turned off to increase the potential of the epitaxial layer in the low-voltage region.

FIGS. 6A-6S are sectional views in the process of preparing a silicon carbide high and low voltage integrated device by the method shown in FIG. 5 according to one embodiment of the application. In FIG. 6A, an N-type silicon carbide substrate 110 is acquired; in FIG. 6B, an N-type drift region 120 is epitaxially growth on the N-type substrate 110; in FIG. 6C, a second P-type doped region 122 is formed by ion implantation; in FIG. 6D, a first P-type doped region 10126 is formed by ion implantation; in FIG. 6E, first N-type doped regions 10124 are formed by ion implantation; in FIG. 6F, a P-type epitaxial layer is grown on the drift region to form a first epitaxial layer 10130 and a third epitaxial layer 30130; in FIG. 6G, a third N-type doped region 30132 is formed by ion implantation; in FIG. 6H, a second N-type doped region 20132 is formed by ion implantation; in FIG. 6I, a third P-type doped region 30134 and a fourth P-type doped region 40134 are formed by ion implantation; in FIG. 6J, a first P-type heavily doped region 10136, a second P-type heavily doped region 201361, a third P-type heavily doped region 201362, a fourth P-type heavily doped region 30136, a fifth P-type heavily doped region 401361, a sixth P-type heavily doped region 401362 and a seventh P-type heavily doped region 50136 are formed by ion implantation; in FIG. 6K, first N-type heavily doped regions 10138, a second N-type heavily doped region 20138, a third N-type heavily doped region 301381, a fourth N-type heavily doped region 301382, a fifth N-type heavily doped region 40138, a sixth N-type heavily doped region 201383, a seventh N-type heavily doped region 501381 and an eighth N-type heavily doped region 501382 are formed by ion implantation, and high-temperature annealing is performed; in FIG. 6L, a second planar gate-oxide dielectric 20146, a third planar gate-oxide dielectric 30146 and a fourth planar gate-oxide dielectric 40146 are grown on the first epitaxial layer 10130, the third epitaxial layer 30130 and the second N-type doped region 20132 by wet oxidation; in FIG. 6M, a second polysilicon gate 20147, a third polysilicon gate 30147 and a fourth polysilicon gate 40147 are deposited on the second planar gate-oxide dielectric 20146, the third planar gate-oxide dielectric 30146 and the fourth planar gate-oxide dielectric 40146 respectively; in FIG. 6N, trenches are formed in the first epitaxial layer 10130, the third epitaxial layer 30130 and the second N-type doped region 20132 and an oxide is deposited to form a first isolation trench 23144, a second isolation trench 12144 and an oxide trench; in FIG. 6O, etching is performed in the oxide trench to form a first trench gate-oxide dielectric 10146, and polysilicon is deposited in the first trench gate-oxide dielectric 10146 to form a first polysilicon gate 10147; in FIG. 6P, an interlayer dielectric 140 is deposited on the second planar gate-oxide dielectric 20146, the third planar gate-oxide dielectric 30146 and the fourth planar gate-oxide dielectric 40146 and distributed all over a device surface; in FIG. 6Q, through-holes are etched in the interlayer dielectric 140; in FIG. 6R, metal is deposited in the through-holes in the interlayer dielectric 140; in FIG. 6S, the metal is etched to form a first source metal electrode 101521, a second source metal electrode 201521, a second drain metal electrode 201522, a third source metal electrode 301521, a third drain metal electrode 301522, a fourth source metal electrode 401521, a fourth drain metal electrode 401522, a first gate metal electrode 401523, a fifth source metal electrode 501521 and a fifth drain metal electrode 501522, metal is deposited in a high-voltage region 10 on the other surface of the N-type substrate 110, and a first drain metal electrode 101522 is formed.

It should be understood that although the steps in the flow diagram of the application are sequentially displayed as indicated by the arrows, these steps will not be definitely executed in the sequence indicated by the arrows. Unless otherwise expressly stated, the sequence for executing the steps is not strictly limited, and these steps may be executed in other sequences. In addition, at least part of the steps in the flow diagram of the application may include multiple steps or stages, these steps or stages will not be definitely completed at the same time and may be executed at different times, and these steps or stages may not be executed in sequence and may be executed in turn or alternately with other steps or steps or stages in other steps.

In the description of the invention, reference terms such as “some embodiments,” “other embodiments” and “desired embodiments” are intended to indicate that specific features, structures, materials or characteristics described in conjunction with said embodiments or examples should be included in at least one embodiment or example of the invention. Here, illustrative descriptions of these terms do not definitely indicate identical embodiments or examples.

The technical features in the above embodiments may be combined arbitrarily. For the sake of a brief description, not all possible combinations of the technical features in the above embodiments are described, and all combinations of these technical features obtained without conflicts should fall within the scope of the invention.

The above embodiments merely present several implementations of the application and are specifically described in detail, but they should not be construed as limitations of the patent scope of the application. It should be noted that those ordinarily skilled in the art can make some improvements and transformations without deviating from the concept of the application, and all these improvements and transformations should also fall within the protection scope of the application. Therefore, the protection scope of the application should be defined by the appended claims.

What is claimed is:

1. An isolation structure for an N epitaxy-based silicon carbide device, comprising an N-type substrate, wherein an N-type drift region is arranged on the N-type substrate, a first isolation trench in which an oxide is deposited and a second isolation trench in which the oxide is deposited are arranged on the N-type drift region to form a high-voltage region, a low-voltage region and a level shift region, a second P-type doped region is arranged at a bottom of the low-voltage region and a bottom of the level shift region, a second N-type doped region is arranged on the second P-type doped region in the low-voltage region, and back-to-back PN junctions are formed by the N-type drift region, the second P-type doped region in the low-voltage region and the second N-type doped region.

2. An N epitaxy-based silicon carbide high and low voltage integrated device, comprising:
an isolation structure, wherein the isolation structure comprises an N-type substrate, an N-type drift region is arranged on the N-type substrate, a first isolation trench-in which an oxide is deposited and a second isolation trench in which the oxide is deposited are arranged on the N-type drift region to form a high-voltage region, a low-voltage region and a level shift region, a second P-type doped region is arranged at a bottom of the low-voltage region and a bottom of the level shift region, a second N-type doped region is arranged on the second P-type doped region in the low-voltage region, and back-to-back PN junctions are formed by the N-type drift region-the second P-type doped region in the low-voltage region, and the second N-type doped region;
a power DMOS device is arranged in the high-voltage region, low-voltage devices are arranged in the low-voltage region, and a high-voltage LDMOS device is arranged in the level shift region;
a sixth N-type heavily doped region is arranged on the second N-type doped region, a third epitaxial layer is arranged on the second P-type doped region-in the level shift region, a third N-type doped region is arranged on the third epitaxial layer, a seventh N-type heavily doped region used as a drain of the high-voltage LDMOS device is arranged on the third N-type doped region, and the sixth N-type heavily doped region is connected to the seventh N-type heavily doped region by means of a fifth drain metal electrode to control a potential of the second N-type doped region.

3. The N epitaxy-based silicon carbide high and low voltage integrated device according to claim 2, wherein the low-voltage devices comprise a low-voltage PMOS device, a low-voltage NMOS device and a low-voltage JFET device.

4. The N epitaxy-based silicon carbide high and low voltage integrated device according to claim 3, wherein the low-voltage PMOS device comprises a second P-type heavily doped region, a third P-type heavily doped region and a second N-type heavily doped region which are arranged on the second N-type doped region, a second source metal electrode is connected to the second N-type heavily doped region and the third P-type heavily doped region and forms a source of the low-voltage PMOS device, a second drain metal electrode is connected to the second P-type heavily doped region and forms a drain of the low-voltage PMOS device an interlayer dielectric is arranged between the second N-type doped region, the second N-type heavily doped region, the second P-type heavily doped region and the third P-type heavily doped region and the second source metal electrode and the second drain metal electrode, a second planar gate-oxide dielectric is arranged on the second N-type doped region-between the source and the drain of the low-voltage PMOS device and a second polysilicon gate is arranged on the second planar gate-oxide dielectric and used as a gate of the low-voltage PMOS device.

5. The N epitaxy-based silicon carbide high and low voltage integrated device according to claim 4, wherein a third P-type doped region is arranged on the second N-type doped region the low-voltage NMOS device is arranged in the third P-type doped region and comprises a third N-type heavily doped region, a fourth N-type heavily doped region and a fourth P-type heavily doped region which are arranged on the third P-type doped region, the interlayer dielectric is arranged on the third P-type doped region, the third N-type heavily doped region, the fourth N-type heavily doped region and the fourth P-type heavily doped region, a third source metal electrode and a third drain metal electrode are arranged on the interlayer dielectric, the third source metal electrode is connected to the fourth P-type heavily doped region and the fourth N-type heavily doped region and forms a source of the low-voltage NMOS device, the third drain metal electrode is connected to the third N-type heavily doped region and forms a drain of the low-voltage NMOS device, a third planar gate-oxide dielectric is arranged on the interlayer dielectric, and a third polysilicon gate is arranged on the third planar gate-oxide dielectric and forms a gate of the low-voltage NMOS device.

6. The N epitaxy-based silicon carbide high and low voltage integrated device according to claim 4, wherein a fourth P-type doped region is arranged on the second N-type doped region, the low-voltage JFET device is arranged in the fourth P-type doped region and comprises a fifth P-type heavily doped region, a sixth P-type heavily doped region and a fifth N-type heavily doped region which are arranged on the fourth P-type doped region, the interlayer dielectric is arranged on the fourth P-type doped region, the fifth P-type heavily doped region, the sixth P-type heavily doped region and the fifth N-type heavily doped region a fourth source metal electrode, a fourth drain metal electrode and a first gate metal electrode are arranged on the interlayer dielectric, the fourth source metal electrode is connected to the sixth P-type heavily doped region and forms a source of the low-voltage JFET device, the fourth drain metal electrode is connected to the fifth P-type heavily doped region and forms a drain of the low-voltage JFET device, and the first gate metal electrode is connected to the fifth N-type heavily doped region and forms a gate of the low-voltage JFET device.

7. The N epitaxy-based silicon carbide high and low voltage integrated device according to claim 6, wherein the power DMOS device comprises a first P-type doped region arranged on the N-type drift region in the high-voltage region, and first N-type doped regions are arranged on two sides of the first P-type doped region; a first epitaxial layer is arranged on the first N-type doped regions, a first P-type heavily doped region is arranged on the first epitaxial layer, a first polysilicon gate wrapped by a first trench gate-oxide dielectric is arranged on the first P-type doped region and forms a gate of the power DMOS device, first N-type heavily doped regions are arranged on two sides of the first trench gate-oxide dielectric respectively and located in the first epitaxial layer, the interlayer dielectric is arranged on the first trench gate-oxide dielectric, the first polysilicon gate, the first P-type heavily doped region and the first N-type heavily doped regions, a first source metal electrode is arranged on the interlayer dielectric, the first source metal electrode is connected to the first P-type heavily doped region and the first N-type heavily doped regions and forms a source of the DMOS device, and a first drain metal electrode is arranged on the N-type substrate and used as a drain of the power DMOS device.

8. The N epitaxy-based silicon carbide high and low voltage integrated device according to claim 7, wherein the high-voltage LDMOS device further comprises a seventh P-type heavily doped region and an eighth N-type heavily doped region which are arranged in the third epitaxial layer in the level shift region, the interlayer dielectric is arranged on the third epitaxial layer the seventh P-type heavily doped region, the eighth N-type heavily doped region, the third N-type doped region and the seventh N-type heavily doped region, a fifth source metal electrode is arranged on the interlayer dielectric, the fifth source metal electrode is connected to the seventh P-type heavily doped region and the eighth N-type heavily doped region and forms a source of the high-voltage LDMOS device, a fourth planar gate-oxide dielectric is arranged between the interlayer dielectric and the third epitaxial layer and located between the eighth N-type heavily doped region and the third N-type doped region, and a fourth polysilicon gate is arranged on the fourth planar gate-oxide dielectric and used as a gate of the high-voltage LDMOS device.

9. A preparation method for an N epitaxy-based silicon carbide high and low voltage integrated device, comprising the following steps:
acquiring a silicon carbide N-type substrate;
epitaxially growing an N-type drift region on one surface of the silicon carbide N-type substrate; performing ion implantation on the N-type drift region to form a second P-type doped region, a first P-type doped region and first N-type doped regions,
growing a P-type epitaxial layer on surfaces of the second P-type doped region, part of the N-type drift region, the first P-type doped region and the first N-type doped regions, and forming a first epitaxial layer and a third epitaxial layer;
performing ion implantation on the third epitaxial layer above the second P-type doped region to form a third N-type doped region and a second N-type doped region; then, performing ion implantation on the third N-type doped region to form a third P-type doped region and a fourth P-type doped region;
performing ion implantation on the first epitaxial layer above the first N-type doped regions, the second N-type doped region, the third P-type doped region, the fourth P-type doped region and the third epitaxial layer to form a first P-type heavily doped region, a second P-type heavily doped region, a third P-type heavily doped region, a fourth P-type heavily doped region, a fifth P-type heavily doped region, a sixth P-type heavily doped region, and a seventh P-type heavily doped region;
performing ion implantation to form first N-type heavily doped regions, a number of which is twice that of the first P-type heavily doped region, in the first epitaxial layer above the first N-type doped regions, form a second N-type heavily doped region and a sixth N-type heavily doped region in the second N-type doped region, form a third N-type heavily doped region and a fourth N-type heavily doped region in the third P-type doped region, form a fifth N-type heavily doped region in the fourth P-type doped region, form a seventh N-type heavily doped region in the third N-type doped region, and form an eighth N-type heavily doped region in the third epitaxial layer;
performing wet oxidation after high-temperature annealing, growing a gate-oxide dielectric on a surface of a current local device structure, and taking the gate-oxide dielectric above the second N-type doped region between the second P-type heavily doped region and the third P-type heavily doped region as a second planar gate-oxide dielectric, the gate-oxide dielectric above the third P-type doped region between the third N-type heavily doped region and the fourth N-type heavily doped region as a third planar gate-oxide dielectric, and the gate-oxide dielectric above the third epitaxial layer between the third N-type doped region and the eighth N-type heavily doped region as a fourth planar gate-oxide dielectric;
respectively, depositing a second polysilicon gate, a third polysilicon gate and a fourth polysilicon gate on the second planar gate-oxide dielectric, the third planar gate-oxide dielectric and the fourth planar gate-oxide dielectric;
respectively, etching trenches between the first epitaxial layer and the second N-type doped region, between the second N-type doped region and the third epitaxial layer, and in the first epitaxial layer above the first P-type doped region and depositing an oxide to form a first isolation trench, a second isolation trench and an oxide trench, performing etching in the oxide trench and forming a first trench gate-oxide dielectric, and depositing polysilicon in the first trench gate-oxide dielectric to form a first polysilicon gate and
depositing an oxide layer on a device surface in a current state to form an interlayer dielectric, etching through-holes in the interlayer dielectric and depositing a metal layer on the interlayer dielectric, and etching the metal layer to form a first source metal electrode, a second drain metal electrode, a second source metal electrode, a third drain metal electrode, a third source metal electrode, a fourth drain metal electrode, a first gate metal electrode, a fourth source metal electrode, a fifth drain metal electrode and a fifth source metal electrode; depositing metal in a high-voltage region on the other surface of the N-type substrate, and forming a first drain metal electrode.

10. The N epitaxy-based silicon carbide high and low voltage integrated device according to claim 5, wherein a fourth P-type doped region is arranged on the second N-type doped region, the low-voltage JFET device is arranged in the fourth P-type doped region and comprises a fifth P-type heavily doped region, a sixth P-type heavily doped region and a fifth N-type heavily doped region which are arranged on the fourth P-type doped region, the interlayer dielectric is arranged on the fourth P-type doped region, the fifth P-type heavily doped region, the sixth P-type heavily doped region and the fifth N-type heavily doped region, a fourth source metal electrode, a fourth drain metal electrode and a first gate metal electrode are arranged on the interlayer dielectric, the fourth source metal electrode is connected to the sixth P-type heavily doped region and forms a source of the low-voltage JFET device, the fourth drain metal electrode is connected to the fifth P-type heavily doped region and forms a drain of the low-voltage JFET device, and the first gate metal electrode is connected to the fifth N-type heavily doped region and forms a gate of the low-voltage JFET device.

11. The N epitaxy-based silicon carbide high and low voltage integrated device according to claim 10, wherein the power DMOS device comprises a first P-type doped region arranged on the N-type drift region in the high-voltage region, and first N-type doped regions are arranged on two sides of the first P-type doped region; a first epitaxial layer is arranged on the first N-type doped regions, a first P-type heavily doped region is arranged on the first epitaxial layer, a first polysilicon gate wrapped by a first trench gate-oxide dielectric is arranged on the first P-type doped region and forms a gate of the power DMOS device, first N-type heavily doped regions are arranged on two sides of the first trench gate-oxide dielectric respectively and located in the first epitaxial layer, the interlayer dielectric is arranged on the first trench gate-oxide dielectric, the first polysilicon gate, the first P-type heavily doped region and the first N-type heavily doped regions, a first source metal electrode is arranged on the interlayer dielectric, the first source metal electrode is connected to the first P-type heavily doped region and the first N-type heavily doped regions and forms a source of the DMOS device, and a first drain metal electrode is arranged on the N-type substrate and used as a drain of the power DMOS device.

12. The N epitaxy-based silicon carbide high and low voltage integrated device according to claim 11, wherein the high-voltage LDMOS device further comprises a seventh P-type heavily doped region and an eighth N-type heavily doped region which are arranged in the third epitaxial layer in the level shift region, the interlayer dielectric is arranged on the third epitaxial layer, the seventh P-type heavily doped region, the eighth N-type heavily doped region, the third N-type doped region and the seventh N-type heavily doped region, a fifth source metal electrode is arranged on the interlayer dielectric, the fifth source metal electrode is connected to the seventh P-type heavily doped region and the eighth N-type heavily doped region and forms a source of the high-voltage LDMOS device, a fourth planar gate-oxide dielectric is arranged between the interlayer dielectric and the third epitaxial layer and located between the eighth N-type heavily doped region and the third N-type doped region, and a fourth polysilicon gate is arranged on the fourth planar gate-oxide dielectric and used as a gate of the high-voltage LDMOS device.
